(19) United States
(12) Patent Application Publication
(10) Pub. No.: US 2006/0089264 A1
(43) Pub. Date: Apr. 27, 2006

(54) Method of heat treating HTc conductors in a large fabricated system

(76) Inventor: Seungok Hong, New Providence, NJ (US)

Correspondence Address: KLAUBER & JACKSON, 411 HACKENSACK AVENUE, HACKENSACK, NJ, 07601, US

(21) Appl. No.: 11/065,434

(22) Filed: Feb. 24, 2005

Related U.S. Application Data
(60) Provisional application No. 60/547,392, filed on Feb. 24, 2004.

(51) Int. Cl. H01L 39/24

(52) U.S. Cl. 505/100

(57) ABSTRACT

An improvement in the method for preparing a high temperature superconductor (HTc) by subjecting a precursor conductor for the high temperature superconductor to a heat treatment schedule to enable formation of the superconducting phases of the HTc. In the improvement precursor conductor is disposed about a central heating element which is subsequently activated to heat the element in accordance with the desired heat treatment schedule to thereby effect corresponding heat treatment of the precursor conductor. This avoids the need e.g. to subject an entire wound magnet to heating in an enclosure in order to convert the magnet winding to a superconductor.

### RELATED APPLICATION

This application claims priority from U.S. Provisional Application Ser. No. 60/547,392 filed Feb. 24, 2004.

### FIELD OF INVENTION

This invention relates generally to high temperature superconductors, and more specifically relates to a method for heat treatment of the precursor assemblies for such superconductors.

### BACKGROUND OF INVENTION

High temperature superconductors (HTcs) must be precisely heat-treated to develop their maximum high current density. In the laboratory small sample lengths of conductors are heat-treated to obtain the maximum current density. FIG. 1 shows a typical heat-treating cycle that must be employed to produce these high currents. The temperature of heat treatment is very high, and radiation is the major source of heat-transfer. Most high temperature furnaces have heating sources at the furnace walls. This permits only a few layers of conductor to be uniformly heat-treated. It is not feasible to maintain a uniform temperature for the entire load. It is very difficult, if not impossible, to uniformly heat a large amount of material by these conventional means.

Furthermore, because of the very brittle nature of the heat-treated conductor any magnet or other device is made by the “wind and react method”, e.g. a magnet is wound with the wire conductor which is the precursor for the superconductor, and then the wound structure is heat treated in a furnace for an ideal superconducting performance. The winding depth and height are rather high, and it is very difficult to perform an ideal heat treatment for such a wound coil.

### SUMMARY OF INVENTION

Now in accordance with the present invention, the superconductor precursor wires or strands are disposed about a central heating element, whereby the heating element can provide direct input heating to the surrounding wires or strands, in accordance with the desired heat treatment schedule. The internal heater additionally serves as reinforcement for the conductors, i.e., by increasing the mechanical strength.

### BRIEF DESCRIPTION OF DRAWINGS

In the drawings:

FIG. 1 is a prior art graphing of a typical heat treatment schedule used with HTcS; and

FIG. 2 is a schematic simplified cross sectional view of a superconductor precursor structure in accordance with the present invention.

### DESCRIPTION OF PREFERRED EMBODIMENT

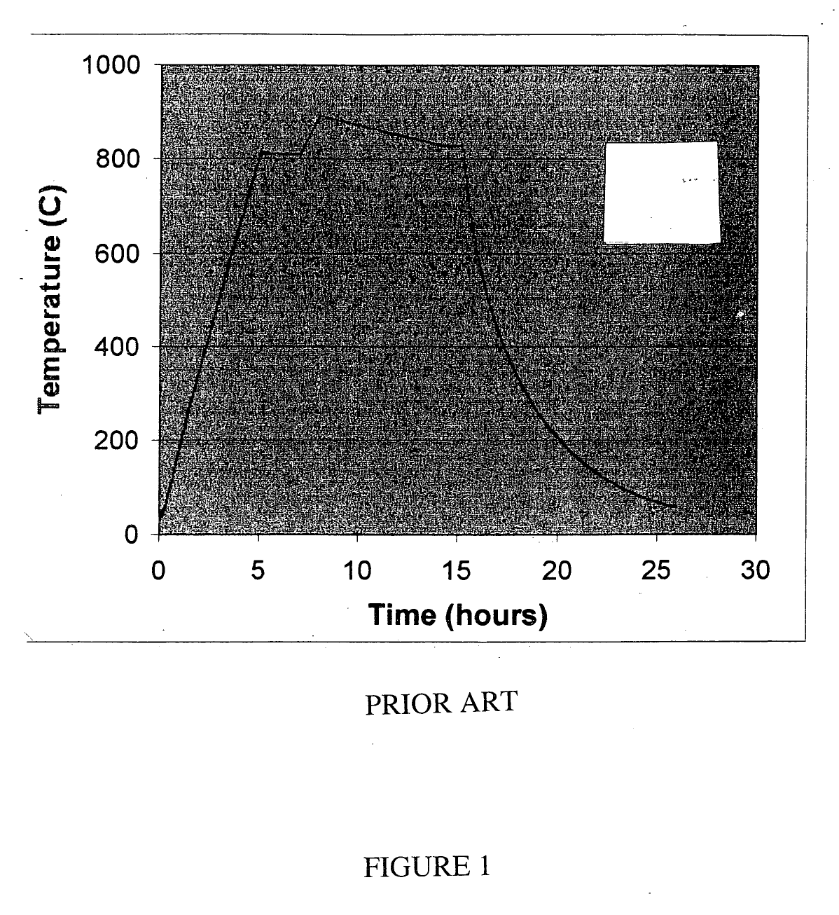

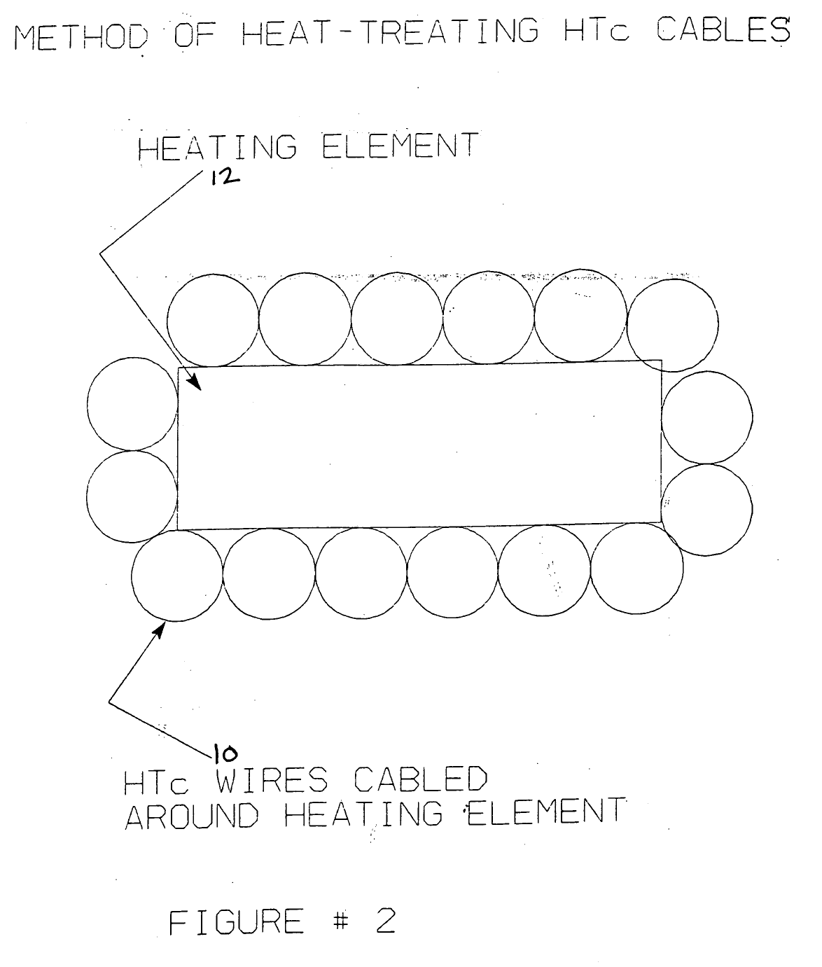

The following illustratively assumes that the device being fabricated is a magnet, although the method similarly applies to any device or spool of cable. As shown in FIG. 2, cable 10, such as a Rutherford Cable (see for example U.S. Pat. Nos. 4,947,637 and 4,529,837 for description of the Rutherford cable) is fabricated around a central heating element or core 12. After the magnet is fabricated using nonheat-treated HT superconductor strand, the heating element 12 is energized to heat the winding in a series of scheduled steps as outlined e.g. in FIG. 1. The heating element may be coated with a thin layer of high temperature insulation. The heating element can be a simple heating wire or cable or it can incorporate additional elements to distribute the heat. The heating element can incorporate a heat pipe to insure maximum uniformity. The jacket of the heat pipe is the heating element and the core; the heat pipe distributes the heat.

The heater element or core 12 also acts as a reinforcing element. Because of the high field environment in a superconducting magnet very high magnetic forces are produced, which in turn generate very large strains on the conductor, which could result in damage to the usually brittle superconductor.

In even a moderately large device it is almost impossible to heat-treat the entire object using a conventional furnace or, for that matter, any heating device that uses external heating. Because of the mass of the device, even if a relatively small one, external heating cannot control the heat-treatment process. As can be seen from FIG. 1, ramp rates are critical, and very importantly the hold time at about 800° C. Most critical is the peak temperature of slightly under 900° C. Exceeding this temperature by only a few degrees will result in inferior superconducting properties. The present invention enables reproduction of this cycle by heating the conductor using internal heaters in close proximity to the superconductor precursor material.

The heating element core 12 may also be a thermostatically formulated conductor which abruptly changes resistance at a preset temperature. While this is useful for only a single set temperature, not a progression of different temperatures, it can be set for the highest temperature that is the most critical. Two heating elements in a parallel-series arrangement can also control the temperature. One element is the thermostatic wire and the other a normal heating element. At intervals they are connected. When the thermostatic heater reaches temperature it will cut off. The overall wattage dissipated in that section will drop. This controls the heat input in the entire magnet in as short an increment as required. The thermostatic wires do not require any mechanical relays or any extra volume over a normal heating element. It is also possible to use a hollow central tube, connected to a high-pressure pump. The pump circulates a heat transfer fluid from a reservoir programmed to the temperature cycle required.

Thus in the present invention a high temperature oxide superconductor assembly is provided consisting of a central heating element upon which high temperature oxide superconductor strands are cabled. A high temperature oxide superconductor magnet or other device is thus heat-treated by the use of internal heaters. The use of the internal heater serves as well to create a reinforcing mechanical strength in the superconductor coil or the like.

While the present invention has been described in terms of specific embodiments thereof, it will be understood in view of the present disclosure, that numerous variations upon the invention are now enabled to those skilled in the art, which variations yet reside within the scope of the present teaching. Accordingly, the invention is to be broadly construed, and limited only by the scope and spirit of the claims now appended hereto.

1. In the method for preparing a high temperature superconductor (HTc) by subjecting a precursor conductor for said high temperature superconductor to a desired heat treatment schedule to enable formation of the superconducting phases of the HTc;
the improvement wherein;
said precursor conductor is disposed about a central heating element which is subsequently activated to heat said element in accordance with said desired heat treatment schedule to thereby effect corresponding heat treatment of the precursor conductor disposed about said element.

2. A method in accordance with claim 1 wherein said precursor conductor is a Rutherford cable.

3. A method in accordance with claim 1 wherein said precursor conductor together with said central heating element are wound about a magnet prior to said heating in order to fabricate a high field magnet without requiring that the precursor conductor together with the magnet be subjected to said heat treatment schedule by means of a heated enclosure.

4. A method in accordance with claim 1 wherein the heating element is a heating wire or cable.

5. A method in accordance with claim 1 wherein said heating element is a heat pipe.

6. A method in accordance with claim 1, wherein said heating element is coated with a thin layer of high temperature insulation.

7. A method in accordance with claim 1, herein said heating element comprises a hollow central tube and means to circulate a heat transfer fluid therein from a reservoir programmed to the temperature cycle desired.

8. A superconductor precursor structure for use in fabricating superconducting magnets, comprising:
a precursor conductor for an HTc which requires subjection to a heat treatment schedule in order to form superconducting phases therein, and a central activatable heating element about which said precursor conductor is disposed;
whereby said structure may be wound about said magnet prior to formation of relatively brittle superconducting phases at said precursor conductor, and thereupon subjected to the desired heat treatment schedule by activation of said heating element.

9. A structure in accordance with claim 8 which is a precursor for a Rutherford cable.

10. A structure in accordance with claim 8 wherein said central heating element is an electrically activated wire or cable.

11. A structure in accordance with claim 8 wherein said central heating element is a heat pipe.

12. A structure in accordance with claim 8, wherein said central heating element is coated with a thin layer of high temperature insulation.

13. A structure in accordance with claim 8, wherein said heating element comprises a hollow central tube and means to circulate a heat transfer fluid therein from a reservoir programmed to the temperature cycle desired.
